(19) United States
(12) Patent Application Publication
(10) Pub. No.: US 2024/0405059 A1
(43) Pub. Date: Dec. 5, 2024

(54) DISPLAY DEVICE

(71) Applicant: Japan Display Inc., Tokyo (JP)

(72) Inventors: Daiki ISONO, Tokyo (JP); Kazuyuki YAMADA, Tokyo (JP); Keisuke ASADA, Tokyo (JP); Kenichi TAKEMASA, Tokyo (JP)

(21) Appl. No.: 18/675,253

(22) Filed: May 28, 2024

(30) Foreign Application Priority Data
Jun. 2, 2023 (JP) 2023-091842

(51) Int. Cl. H01L 27/15

(52) U.S. Cl. CPC H01L 27/156

(57) ABSTRACT

A display device includes a substrate having a first main surface on which a plurality of light emitting elements spaced apart from each other are provided and a second main surface located on a side opposite to the first main surface, a cooling unit having a third main surface and a fourth main surface located on a side opposite to the third main surface, a heat dissipation sheet located between the second main surface and the third main surface and in contact with the second main surface and the third main surface, and a connection portion arranged at a position sandwiching the heat dissipation sheet in a direction along the second main surface and bonded to each of the substrate and the cooling unit, and the connection portion is made of a heat shrinkable resin.

### CROSS REFERENCES TO RELATED APPLICATIONS

The present application claims priority to Japanese Patent Application No. 2023-091842 filed on Jun. 2, 2023, the disclosure of which is incorporated herein by reference.

### TECHNICAL FIELD

The present invention relates to a display device having a cooling mechanism.

### BACKGROUND

There is a display device (for example, micro LED display) configured by arranging a plurality of minute self-luminous light emitting elements (for example, light emitting diodes) on a circuit board with high transmittance. Since light loss is low in such a display device because it does not use reflection or diffusion, and it is possible to achieve high brightness.

Patent Document 1 (Japanese Unexamined Patent Application Publication No. 2003-124671) discloses that a heat dissipation pipe is arranged on a back side of a display inside a display case of a notebook personal computer and the display is cooled by cooling water flowing through the heat dissipation pipe.

Patent Document 2 (Japanese Unexamined Patent Application Publication No. 2016-119362) discloses that thin metal wires are formed in a grid pattern on a back surface of a transparent organic EL panel and the thin metal wires are covered with a transparent heat dissipation sheet.

### SUMMARY

When the high brightness display is performed on a display device in which self-luminous light emitting elements are arranged on a board, the heat generated by the elements themselves and circuits on the board may pose some problems. Namely, the reduction in light emission efficiency due to the temperature rise in the elements and the damage to the elements or circuits due to high temperature may occur.

One measure to prevent the temperature rise is to cool the heat generating parts by using a heat sink or the like. However, for example, in a case where elements are exposed on a surface of a display device, it is difficult to overlap a display panel and a cooling mechanism and press them from front and back sides into close contact because it causes the damage to the elements.

An object of the present invention is to improve the performance of the display device.

Other objects and novel features will be apparent from the description of this specification and the accompanying drawings.

An outline of a typical embodiment disclosed in this application will be briefly described as follows.

A display device according to an embodiment includes a substrate having a first main surface on which a plurality of light emitting elements spaced apart from each other are provided and a second main surface located on a side opposite to the first main surface, a cooling unit having a third main surface and a fourth main surface located on a side opposite to the third main surface, a heat dissipation sheet located between the second main surface and the third main surface and in contact with the second main surface and the third main surface, and a connection portion arranged at a position sandwiching the heat dissipation sheet in a direction along the second main surface and bonded to each of the substrate and the cooling unit, and the connection portion is made of a heat shrinkable resin.

### BRIEF DESCRIPTION OF DRAWINGS

FIG. 1 is a cross-sectional view showing a display device according to the first embodiment;

FIG. 2 is a plan view showing the display device according to the first embodiment;

FIG. 3 is a perspective view showing the display device according to the first embodiment;

FIG. 4 is a cross-sectional view showing a cooling unit constituting the display device according to the first embodiment;

FIG. 5 is a cross-sectional view taken along the line A-A in FIG. 4;

FIG. 6 is a cross-sectional view showing a method of manufacturing the display device according to the first embodiment;

FIG. 7 is a cross-sectional view showing the method of manufacturing the display device subsequent to FIG. 6;

FIG. 8 is a cross-sectional view showing a display device according to a first modification of the first embodiment;

FIG. 9 is a cross-sectional view showing a display device according to a second modification of the first embodiment;

FIG. 10 is a plan view showing a display device according to a third modification of the first embodiment;

FIG. 11 is a cross-sectional view showing a display device according to the second embodiment;

FIG. 12 is a perspective view showing the display device according to the second embodiment;

FIG. 13 is a perspective view showing the display device according to the second embodiment;

FIG. 14 is a cross-sectional view showing a modification of the display device according to the second embodiment; and

FIG. 15 is a cross-sectional view showing a display device according to a comparative example.

### DETAILED DESCRIPTION OF THE INVENTION

Hereinafter, each embodiment of the present invention will be described with reference to drawings. Note that the disclosure is merely an example, and it is a matter of course that any alteration that is easily made by a person skilled in the art while keeping a gist of the present invention is included in the range of the present invention. In addition, the drawings schematically illustrate a width, a thickness, a shape, and the like of each portion as compared with actual aspects in order to make the description clearer, but the drawings are merely examples and do not limit the interpretation of the present invention. Further, the same elements as those described in relation to the foregoing drawings are denoted by the same or related reference characters in this specification and the respective drawings, and detailed descriptions thereof will be omitted as appropriate.

The planar shape mentioned in this application indicates the shape of an object in plan view. The plan view mentioned here indicates the positional relationship when an object is viewed in a direction perpendicular to the main surface which is a particularly large surface of the object.

### First Embodiment

### <Configuration of Display Device>

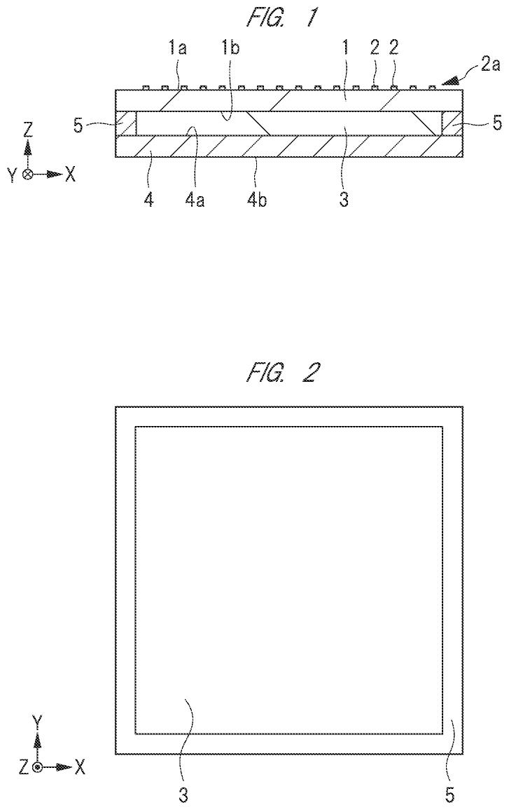

A display device according to the present embodiment will be described with reference to FIG. 1 to FIG. 5.

FIG. 1 is a cross-sectional view showing the display device according to the present embodiment. As shown in FIG. 1, the display device according to the present embodiment includes a substrate 1, a plurality of light emitting elements 2 provided so as to be arranged on the substrate 1, a cooling unit 4 attached to a lower surface of the substrate 1 via a heat dissipation sheet 3, and a connection portion 5 bonded to the lower surface of the substrate 1 and an upper surface of the cooling unit 4.

The substrate 1 has a first main surface 1a and a second main surface 1b on a side opposite to the first main surface 1a. Also, the cooling unit 4 has a third main surface 4a and a fourth main surface 4b on a side opposite to the third main surface 4a. The substrate 1 is, for example, a glass substrate (transparent substrate, array substrate) made of glass, and transistors (thin film transistors (TFTs)), a wiring layer including a wiring and an insulating film, and the light emitting elements 2 thereon are provided on the first main surface 1a. Namely, the plurality of light emitting elements 2 spaced apart from each other are provided on the first main surface 1a. The substrate 1 is a drive circuit board for driving each pixel, and is referred to also as a backplane or an active matrix substrate. Here, the substrate 1 provided with the plurality of light emitting elements 2 is referred to as a display panel in some cases.

The plurality of light emitting elements 2 include, for example, light emitting elements to emit red light, light emitting elements to emit green light, and light emitting elements to emit blue light. The light emitting elements for red, green, and blue are arranged together and constitute one pixel. In other words, one pixel is composed of the light emitting elements of three colors. On the first main surface 1a, such pixels are arranged in a matrix in the X direction and the Y direction. Namely, the plurality of light emitting elements 2 are arranged along the first main surface 1a and the second main surface 1b of the substrate 1. A light emitting element mounting portion (display unit) 2a in which the plurality of light emitting elements 2 are arranged is present on the first main surface 1a of the substrate 1. The plurality of light emitting elements 2 are arranged so as to protrude on the first main surface 1a and are all exposed. The main surfaces mentioned in this application are all along the X-Y plane and the direction perpendicular to the main surface (normal direction) is the Z direction.

The X direction and the Y direction are directions orthogonal to each other. However, the X direction may not orthogonally cross the Y direction. In the Z direction orthogonal to each of the X direction and the Y direction, the second main surface 1b of the substrate 1 and the third main surface 4a of the cooling unit 4 face each other. Namely, the substrate 1 and the cooling unit 4 overlap each other in plan view.

The light emitting element 2 is a light emitting diode (LED) having an anode terminal and a cathode terminal. The light emitting element 2 is an LED chip having a size of 3 μm or more and 300 μm or less in plan view. Though not defined strictly, the chip having a chip size of smaller than 100 μm is referred to as a micro LED. The display device provided with the micro LED in each pixel is referred to also as a micro LED display device. Note that the “micro” of the micro LED does not limit the size of the light emitting element 2.

The heat dissipation sheet (heat conducting sheet) 3 is, for example, a plate-shaped portion containing a plurality of carbon fibers and having an adhesiveness. The heat dissipation sheet 3 is in contact with each of the second main surface 1b of the substrate 1 and the third main surface 4a of the cooling unit 4. The heat dissipation sheet 3 is located between the substrate 1 and the cooling unit 4, and is bonded to each of the second main surface 1b and the third main surface 4a. The heat dissipation sheet 3 is made of a material having higher thermal conductivity than any of the substrate 1, the connection portion 5, and pure water.

The cooling unit 4 is, for example, a cooling mechanism capable of dissipating heat by an air or water cooling method. For example, the cooling unit 4 has an approximately plate-like shape having the third main surface 4a along the X-Y plane. The planar shape of the light emitting element mounting portion 2a, the substrate 1, the heat dissipation sheet 3, and the cooling unit 4 is, for example, a rectangular shape. Here, the substrate 1 and the cooling unit 4 have almost the same size in plan view, and the heat dissipation sheet 3 has a smaller size in comparison with them. The light emitting element mounting portion 2a, the heat dissipation sheet 3, and the cooling unit 4 overlap each other in plan view.

The connection portion 5 is made of a heat shrinkable resin. The connection portion 5 is formed by heating a liquid resin to harden and shrink it in the manufacturing process of the display device. Namely, the connection portion 5 is made of a material having heat shrinkability, which is liquid at room temperature and shrinks and hardens when heated. The connection portion 5 which has once heated and hardened does not return to a liquid state even when the temperature returns to room temperature. Specifically, the connection portion 5 is made of, for example, a thermosetting epoxy resin. The shrinkage rate between the liquid resin before heating and the connection portion 5 after shrinking by heating is, for example, 3 to 5%. In other words, the length of the connection portion 5 is reduced by about 3 to 5% due to heating.

The connection portion 5 is bonded to each of the second main surface 1b of the substrate 1 and the third main surface 4a of the cooling unit 4. Namely, the connection portion 5 is in contact with each of the second main surface 1b of the substrate 1 and the third main surface 4a of the cooling unit 4. In other words, the connection portion 5 connects the second main surface 1b and the third main surface 4a together. However, for example, an adhesive may be interposed between the connection portion 5 and the second main surface 1b or between the connection portion 5 and the third main surface 4a.

Here, the connection portion 5 is adjacent to the heat dissipation sheet 3 in each of the X direction and the Y direction, and has the same thickness as the heat dissipation sheet 3 in the Z direction. The connection portion 5 is arranged so as to sandwich the heat dissipation sheet 3 in one or both of the X direction and the Y direction, that is, in the direction along the second main surface 1b. As shown in FIG. 2, the periphery of the rectangular heat dissipation sheet 3 is surrounded by the annular connection portion 5. In other words, the periphery of the heat dissipation sheet 3 is completely surrounded by the connection portion 5 having a continuous annular structure in plan view. Note that illustration of the substrate 1 and the light emitting element 2 is omitted in FIG. 2.

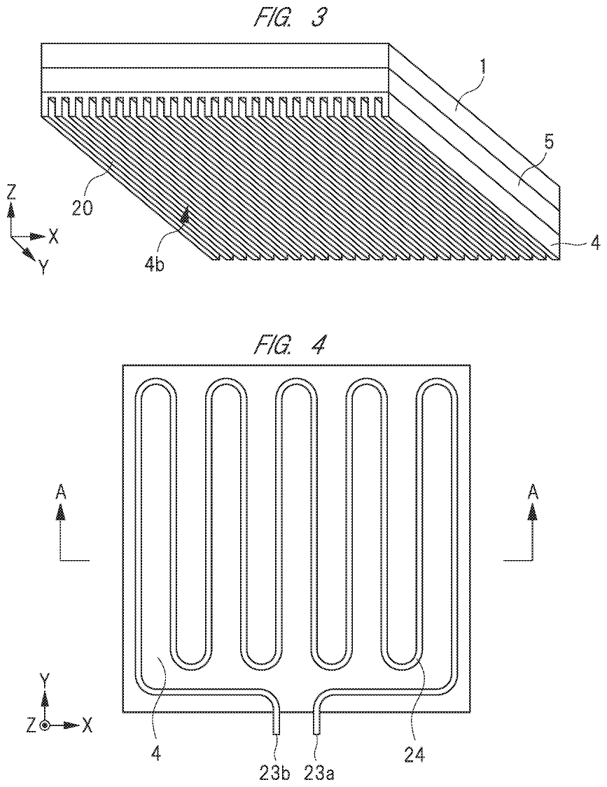

The cooling unit 4 is mainly made of, for example, metal which has higher thermal conductivity than glass and others. When the cooling method of the cooling unit 4 is the air cooling method, it is conceivable that the cooling unit 4 is, for example, a heat sink, and includes fins 20 which are a plurality of convex portions extending in the Y direction as shown in FIG. 3. The plurality of fins 20 are arranged in the X direction. The fins 20 are formed on the side of the fourth main surface 4b of the cooling unit 4. The heat of the cooling unit 4 is taken away by the air flowing around the plurality of fins 20, whereby the cooling unit 4 is cooled.

Furthermore, when the cooling method of the cooling unit 4 is the water cooling method, it is conceivable that the cooling unit 4 includes a flow path 24 which meanders therein in plan view as shown in FIG. 4 and FIG. 5. In this case, the cooling unit 4 has an inlet hole 23a and an outlet hole 23b exposed to the outside. The inlet hole 23a and the outlet hole 23b constitute both ends of the flow path 24, and the cooling medium (for example, liquid such as water) supplied from the inlet hole 23a flows through the flow path 24 and is discharged from the outlet hole 23b. The heat of the cooling unit 4 is taken away by the cooling medium flowing through the flow path 24, whereby the cooling unit 4 is cooled.

In the display device according to the present embodiment, heat generated by the light emitting element 2 or the transistor on the substrate 1 is conducted via the substrate 1 and the heat dissipation sheet 3, and is dissipated in the cooling unit 4. The connection portion 5 has heat shrinkability and thus presses the cooling unit 4 to the substrate 1. The surface of the heat dissipation sheet 3 that faces the second main surface 1b is all in contact with the second main surface 1b. Namely, there is no gap between the heat dissipation sheet 3 and the second main surface 1b in the Z direction. In this way, the heat dissipation sheet 3 is brought into close contact with the second main surface 1b of the substrate 1, thereby enabling effective cooling.

### <Method of Manufacturing Display Device>

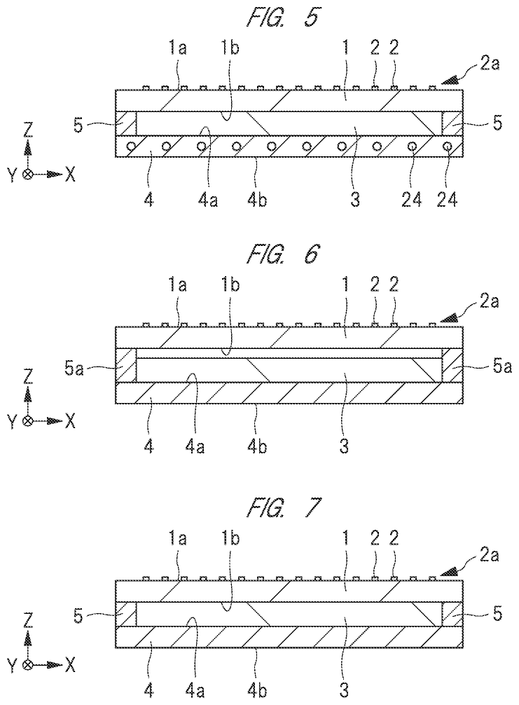

A method of manufacturing the display device according to the present embodiment will be described with reference to FIG. 6 and FIG. 7.

First, the substrate 1 having the plurality of light emitting elements 2 arranged on the first main surface 1a is prepared as shown in FIG. 6. This substrate 1 can be formed by, for example, forming the metal wiring and the transistor on the first main surface 1a of the substrate 1 which is a glass substrate, and then pressing the main surface of a transfer substrate, on which the plurality of light emitting elements 2 diced into pieces from a semiconductor wafer are arranged and adhered, to the first main surface 1a of the substrate 1, thereby transferring the light emitting elements 2 to the first main surface 1a. Also, the cooling unit 4 having the heat dissipation sheet 3 attached to the third main surface 4a is prepared.

Next, the substrate 1, the heat dissipation sheet 3, and the cooling unit 4 are placed in a mold in the state where the second main surface 1b of the substrate 1 and the third main surface 4a of the cooling unit 4 face each other. Subsequently, a liquid resin 5a which is a heat shrinkable resin is poured to a region (space) around the heat dissipation sheet 3 in the direction along the second main surface 1b and between the second main surface 1b and the third main surface 4a. The resin 5a is a resin that shrinks and hardens when heated. At this time, the second main surface 1b of the substrate 1 and the heat dissipation sheet 3 may be in contact with each other in the mold, but may be spaced apart from each other. Inside the mold, the relative positions of the substrate 1 and the cooling unit 4 are not fixed, and one can move so as to approach the other. For example, a thermosetting epoxy resin can be used as the resin 5a.

Next, as shown in FIG. 7, the inside of the mold is heated. The heating temperature at this time is, for example, 100° C. or higher. This heating causes the resin 5a to shrink and harden, whereby the connection portion 5 made of the resin 5a is formed. This shrinkage makes the length of the connection portion 5 in the Z direction shorter than the length of the liquid resin 5a in the Z direction. The substrate 1 and the cooling unit 4 are drawn toward each other due to the force of the connection portion 5 shrinking in the Z direction, and the heat dissipation sheet 3 is brought into close contact with the second main surface 1b of the substrate 1. In other words, the stress acts to press the heat dissipation sheet 3 to the second main surface 1b of the substrate 1.

Through the above steps, the display device capable of dissipating the heat of the substrate 1 (light emitting element 2) to the side of the cooling unit 4 via the heat dissipation sheet 3 is almost completed.

### Effects of Present Embodiment

When a display device generates heat during its use, it is necessary to cool the heat generating parts by a cooling mechanism such as a heat sink in order to prevent damage to light emitting elements or circuits due to high temperature. In a micro LED display device in which the light emitting element (self-luminous light emitting element) is arranged in each pixel, the temperature rise is significant because each light emitting element generates a large amount of heat.

When the substrate 1 which is a display panel and the cooling unit 4 which is a cooling mechanism are bonded to each other by the heat dissipation sheet 3 having an adhesiveness as in the display device according to the comparative example shown in FIG. 15, the heat of the substrate 1 can be conducted to the cooling unit 4 via the heat dissipation sheet 3. However, for example, when the light emitting elements 2 are exposed on the surface (first main surface 1a) of the substrate 1 as in a micro LED display device, it is not possible to press the substrate 1 and the cooling unit 4 overlapping each other from the side of the first main surface 1a of the substrate 1 and the side of the fourth main surface 4b of the cooling unit 4. This is because such pressing would damage the light emitting elements 2 on the first main surface 1a of the substrate 1. As a result, it is probable that the substrate 1 and the heat dissipation sheet 3 cannot be brought into close contact with each other and a gap may be created therebetween. Namely, there is a problem that the second main surface 1b of the substrate 1 and the heat dissipation sheet 3 cannot be brought into close contact with each other and the heat generated in the substrate is difficult to be transmitted to the side of the cooling unit 4.

Even when the light emitting elements 2 on the first main surface 1a are covered with, for example, a transparent protective layer, this problem similarly occurs if the strength of the protective layer is low. Although the heat dissipation sheet 3 has an adhesiveness, its adhesiveness to glass is relatively low. Therefore, when the substrate 1 is made of glass, it is particularly important to press and bond the heat dissipation sheet 3 to the second main surface 1b of the substrate 1.

Therefore, in the present embodiment, the connection portion 5 configured to connect the substrate 1 and the cooling unit 4 and arranged around the heat dissipation sheet 3 in plan view is provided as shown in FIG. 1. The connection portion 5 is made of a heat shrinkable resin that shrinks when heated, and shrinks when heated during the manufacturing process, thereby pressing the heat dissipation sheet 3 and the second main surface 1b of the substrate 1 to each other. As a result, since the heat dissipation sheet 3 and the second main surface 1b of the substrate 1 are in close contact with each other, heat can be efficiently transmitted from the side of the substrate 1 to the side of the cooling unit 4 via the heat dissipation sheet 3. Therefore, it is possible to prevent the temperature rise of the display device while preventing the damage to pixels due to pressing. Accordingly, it is possible to prevent the decrease in luminous efficiency of the light emitting elements due to the temperature rise and to prevent the damage to the elements or circuits due to high temperature. Since it is possible to suppress the temperature rise, it is also possible to further increase the brightness of the light emitting elements. As described above, the performance of the display device can be improved.

### First Modification

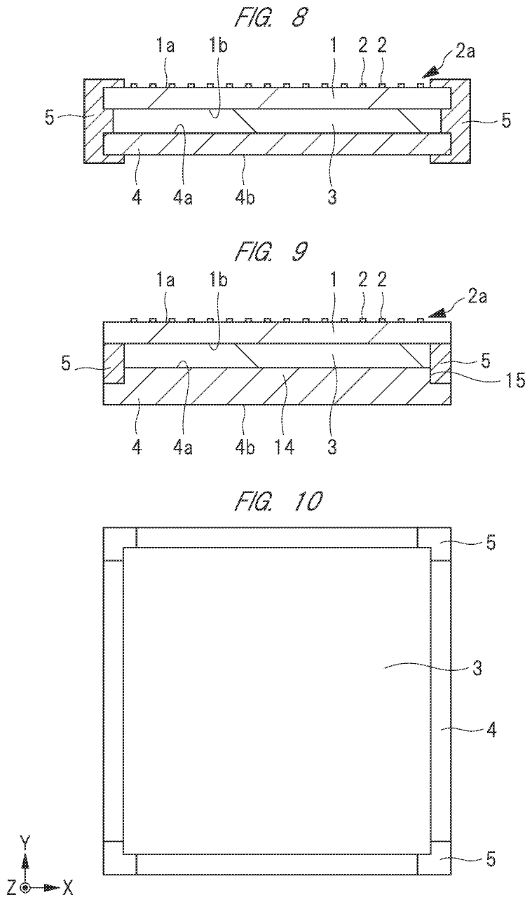

As shown in FIG. 8, the connection portion 5 may cover the side surface of the substrate 1 in the X direction or the Y direction, and a part of the connection portion 5 may also cover an edge portion of the first main surface 1a of the substrate 1. In this case, the pixels (light emitting elements 2) are exposed from the connection portion 5 that covers the first main surface 1a. In other words, the connection portion 5 is bonded to the edge portion of the first main surface 1a, which is the region surrounding the display unit in which the plurality of light emitting elements 2 are arranged in plan view. In addition, the connection portion 5 may cover the side surface of the cooling unit 4 in the X direction or the Y direction, and a part of the connection portion 5 may also cover an edge portion of the fourth main surface 4b of the cooling unit 4. Although both of the edge portion of the first main surface 1a and the edge portion of the fourth main surface 4b are covered with one connection portion 5 in FIG. 8, either the edge portion of the first main surface 1a or the edge portion of the fourth main surface 4b may be exposed as in the display device in FIG. 1. However, from the viewpoint of improving the adhesion between the heat dissipation sheet 3 and the substrate 1 by the shrinkage of the connection portion 5 and preventing the peeling of the connection portion 5, it is preferable that both of the edge portion of the first main surface 1a and the edge portion of the fourth main surface 4b are covered with one connection portion 5 as shown in FIG. 8. Here, the connection portion 5 is bonded to each of the first main surface 1a, the side surface and the fourth main surface 4b of the cooling unit 4.

In this modification, the length of the connection portion 5 in the Z direction increases in comparison with the structure described with reference to FIG. 1. In other words, the length of the connection portion 5 in the Z direction can be made larger than the thickness of the heat dissipation sheet 3 in the Z direction. Therefore, the force to press the heat dissipation sheet 3 to the substrate 1 by the shrinkage of the connection portion 5 can be increased, and the adhesion between the heat dissipation sheet 3 and the substrate 1 can be improved.

Here, since the fourth main surface 4b of the cooling unit 4 is exposed except the edge portion, the cooling efficiency can be improved in comparison with the case where the fourth main surface 4b is entirely covered with the connection portion 5. In particular, when the cooling method of the cooling unit 4 is the air cooling method, the configuration in which the fourth main surface 4b is exposed except the edge portion as in this modification is advantageous from the viewpoint of preventing the reduction in cooling efficiency.

### Second Modification

As shown in FIG. 9, the third main surface 4a of the cooling unit 4 may have a convex portion 14 protruding toward the substrate 1 at the center thereof. In other words, the third main surface 4a of the cooling unit 4 may have a concave portion recessed toward the fourth main surface 4b of the cooling unit 4 at the edge portion (peripheral portion) thereof. The connection portion 5 is bonded to the bottom surface of the concave portion, and the heat dissipation sheet 3 is in contact with the upper surface (surface facing the second main surface 1b of the substrate 1) of the convex portion 14. A step difference 15 is present at the boundary between the upper surface of the convex portion 14 and the bottom surface of the concave portion.

Since the cooling unit 4 has the step difference 15, the length of the connection portion 5 in the Z direction becomes larger than the thickness of the heat dissipation sheet 3. Therefore, the length of the connection portion 5 in the Z direction increases in comparison with the structure described with reference to FIG. 1. Accordingly, the force to press the heat dissipation sheet 3 to the substrate 1 by the shrinkage of the connection portion 5 can be increased, and the adhesion between the heat dissipation sheet 3 and the substrate 1 can be improved.

### Third Modification

The configuration in which the connection portion 5 has an annular structure and surrounds the periphery of the heat dissipation sheet 3 has been described with reference to FIG. 2. Meanwhile, a plurality of connection portions 5 may be separately arranged as shown in FIG. 10. Namely, the plurality of connection portions 5 may be separately arranged so as to surround the periphery of the heat dissipation sheet 3 in plan view.

FIG. 10 shows the structure in which the connection portion 5 is provided at each of four corners of the display device having a rectangular planar shape. Namely, the connection portions 5 are arranged near the four corners of the heat dissipation sheet 3 in plan view.

### Second Embodiment

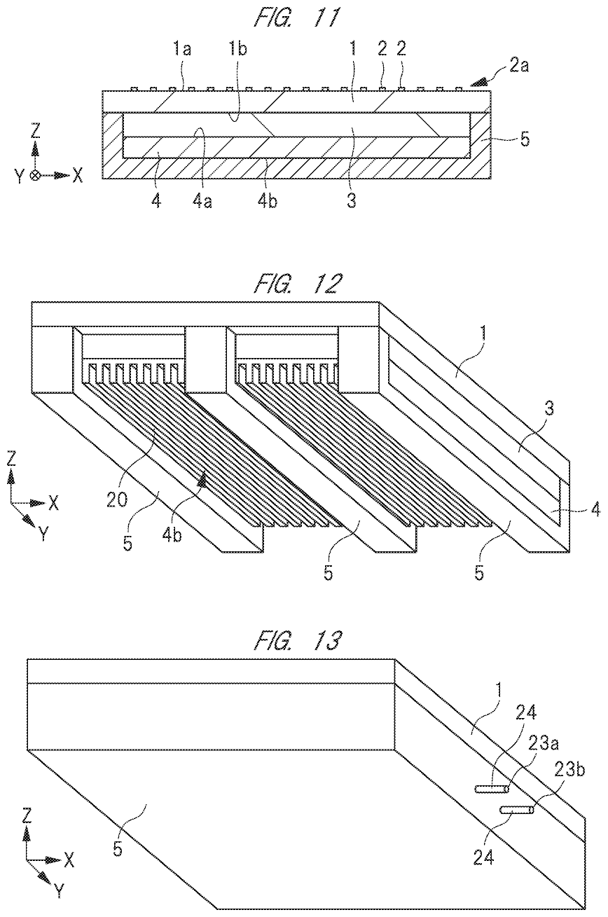

As shown in FIG. 11, the connection portions 5 arranged to be adjacent to both side surfaces of the heat dissipation sheet 3 in the X direction or the Y direction may cover both side surfaces of the cooling unit 4 and may be integrally connected by the connection portion 5 configured to cover the bottom surface of the cooling unit 4.

In this case, the connection portion 5 is not bonded to the third main surface 4a of the cooling unit 4, but the width of the cooling unit 4 in the X direction or the Y direction may be made larger than the width of the heat dissipation sheet 3 as shown in FIG. 8 such that the connection portion 5 is bonded to the third main surface 4a of the cooling unit 4.

The connection portion 5 shown in FIG. 11 continuously covers one side surface of the cooling unit 4 in the X direction or the Y direction, the fourth main surface (bottom surface) 4b of the cooling unit 4, and the other side surface of the cooling unit 4. As shown in FIG. 12, for example, the connection portion 5 may have a strip shape and cover the heat dissipation sheet 3 and the cooling unit 4 at one or more locations. Namely, the fourth main surface 4b of the cooling unit 4 is partially exposed from the connection portion 5. In FIG. 12, three strip-shaped connection portions 5 cover the heat dissipation sheet 3 and the cooling unit 4 at positions spaced apart from each other. Meanwhile, the connection portion 5 may be only one at the center among the three or may be only two at both ends. Moreover, the number of connection portions 5 may be four or more.

When the cooling method of the cooling unit 4 is the air cooling method, the reduction in cooling efficiency can be prevented by providing the strip-shaped connection portions 5 as described above in comparison with the configuration in which the connection portion 5 entirely covers the fourth main surface 4b of the cooling unit 4.

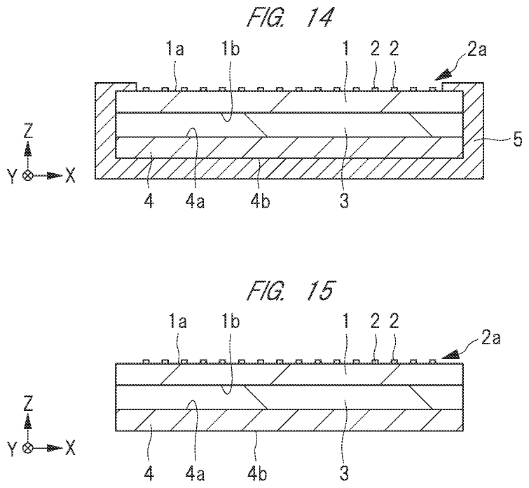

Further, when the cooling method of the cooling unit 4 is the water cooling method, the entire cooling unit 4 may be covered with the connection portion 5 as shown in FIG. 13. However, a part of the flow path 24 penetrates the connection portion 5, and the inlet hole 23a and the outlet hole 23b extending outward from the side surface of the cooling unit 4 in the X direction or the Y direction are exposed from the connection portion 5. In the case of the water cooling method, even if the entire cooling unit 4 is covered with the connection portion 5, the reduction in cooling efficiency can be prevented by circulating the cooling medium through the flow path 24 between the inlet hole 23a and the outlet hole 23b.

In the present embodiment, the length of the connection portion 5 that continuously covers one side surface of the cooling unit 4, the fourth main surface 4b of the cooling unit 4, and the other side surface of the cooling unit 4 is larger than the length of the connection portion 5 formed only between the substrate 1 and the cooling unit 4 shown in FIG. 1. Therefore, the length of the connection portion 5 made of a heat shrinkable resin to be shrunk due to heating is larger than that of the connection portion 5 shown in FIG. 1. Further, the cooling unit 4 and the heat dissipation sheet 3 are sandwiched between the substrate 1 and the connection portion 5, and both ends of the connection portion 5 are bonded to the second main surface 1b of the substrate 1. Therefore, the force to press the heat dissipation sheet 3 to the second main surface 1b of the substrate 1 by the shrinkage of the connection portion 5 can be increased in comparison with the structure shown in FIG. 1. As a result, the adhesion between the heat dissipation sheet 3 and the substrate 1 is improved, and a high heat dissipation effect in the display device can be obtained.

### Modification

Unlike the structure described with reference to FIG. 11, the connection portion 5 may cover the side surface of the substrate 1 in the X direction or the Y direction, and a part of the connection portion 5 may also cover the edge portion of the first main surface 1a of the substrate 1 as shown in FIG. 14. In this case, the pixels (light emitting elements 2) are exposed from the connection portion 5 covering the first main surface 1a.

In this modification, the length of the connection portion 5 in the Z direction increases in comparison with the structure described with reference to FIG. 11. Therefore, the force to press the heat dissipation sheet 3 to the substrate 1 by the shrinkage of the connection portion 5 can be increased, and the adhesion between the heat dissipation sheet 3 and the substrate 1 can be improved.

Further, even if stress is generated in the connection portion 5 in the direction away from the second main surface 1b when the connection portion 5 shrinks due to heating, it is possible to prevent the connection portion 5 from coming off from the substrate 1 because a part of the connection portion 5 covers the edge portion of the first main surface 1a.

In the foregoing, the embodiments and typical modifications have been described, but the above-described technique can be applied to various modifications other than the illustrated modifications.

A person having ordinary skill in the art can make various alterations and corrections within a range of the idea of the present invention, and it is interpreted that the alterations and corrections also belong to the scope of the present invention. For example, the embodiment obtained by performing addition or elimination of components or design change or the embodiment obtained by performing addition or reduction of process or condition change to the embodiment described above by a person having an ordinary skill in the art is also included in the scope of the present invention as long as it includes the gist of the present invention.

The present invention can be used for the manufacture of light emitting devices.

What is claimed is:

1. A display device comprising:
a substrate having a first main surface on which plurality of light emitting elements spaced apart from each other are provided and a second main surface located on a side opposite to the first main surface;
a cooling unit having a third main surface and a fourth main surface located on a side opposite to the third main surface;
a heat dissipation sheet located between the second main surface and the third main surface and in contact with the second main surface and the third main surface; and
a connection portion arranged at a position sandwiching the heat dissipation sheet in a direction along the second main surface and bonded to each of the substrate and the cooling unit,
wherein the connection portion is made of a heat shrinkable resin.

2. The display device according to claim 1,
wherein the connection portion has an annular structure that surrounds a periphery of the heat dissipation sheet in plan view.

3. The display device according to claim 1,
wherein the connection portion is in contact with each of the second main surface and the third main surface.

4. The display device according to claim 1,
wherein the plurality of light emitting elements constitute a display unit, and
wherein each of the heat dissipation sheet and the cooling unit overlaps the display unit in plan view.

5. The display device according to claim 1,
wherein the third main surface includes an upper surface of a protrusion that protrudes toward the substrate and a bottom surface of a concave portion adjacent to the protrusion in plan view,
wherein the heat dissipation sheet is bonded to the upper surface of the protrusion, and
wherein the connection portion is bonded to the bottom surface of the concave portion.

6. The display device according to claim 1,
wherein the plurality of light emitting elements constitute a display unit, and
wherein the connection portion covers an edge portion of the first main surface, which is a region surrounding the display unit in plan view.

7. The display device according to claim 1,
wherein the connection portion covers an edge portion of the fourth main surface.

8. The display device according to claim 1,
wherein each of the connection portions arranged at positions sandwiching the heat dissipation sheet in the direction along the second main surface is integrated with the connection portion that covers a part or all of the fourth main surface.

9. The display device according to claim 8,
wherein a part of the fourth main surface is exposed from the connection portion, and
wherein the cooling unit has a cooling mechanism of an air cooling method.

10. The display device according to claim 8,
wherein the connection portion has an annular structure that surrounds a periphery of the heat dissipation sheet in plan view,
wherein the connection portion entirely covers the fourth main surface, and
wherein the cooling unit has a cooling mechanism of a water cooling method.

11. The display device according to claim 1,
wherein a surface of the heat dissipation sheet facing the second main surface is entirely in contact with the second main surface.

12. The display device according to claim 1,
wherein each of the plurality of light emitting elements is a light emitting diode.
